(19) United States
(12) Patent Application Publication
(10) Pub. No.: US 2025/0194057 A1
(43) Pub. Date: Jun. 12, 2025

(54) Server System Liquid Cooling Leak Detection Information Signal Generation System

(71) Applicant: Dell Products L.P., Round Rock, TX (US)

(72) Inventors: Sandor Farkas, Round Rock, TX (US); Michael J. Stumpf, Cedar Park, TX (US)

(21) Appl. No.: 18/536,890

(22) Filed: Dec. 12, 2023

(51) Int. Cl. H05K 7/20; G08B 5/38

(52) U.S. Cl. CPC H05K 7/20836; G08B 5/38; H05K 7/20763

(57) ABSTRACT

A system and method for reporting presence of liquid within an information handling system via a liquid detection operation. In certain embodiments, the liquid detection operation includes monitoring an information handing system chassis for presence of liquid within the information handing system chassis; determining when liquid is detected within the chassis of the information handing system chassis; and, reporting presence of liquid when liquid is detected within the information handling system chassis, the reporting being via generation of a sequence of light flashes, the sequence of light flashes being based upon a unique signal generation parameter.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information signal for a server system liquid cooling leak detection apparatus.

In one embodiment, the invention relates to a method for reporting presence of liquid within an information handling system, comprising: monitoring an information handing system chassis for presence of liquid within the information handing system chassis; determining when liquid is detected within the chassis of the information handing system chassis; and, reporting presence of liquid when liquid is detected within the information handling system chassis, the reporting being via generation of a sequence of light flashes, the sequence of light flashes being based upon a unique signal generation parameter.

In another embodiment, the invention relates to a system comprising: a chassis; a processor contained within the chassis; a data bus coupled to the processor; a liquid detection system contained within the chassis; and a non-transitory, computer-readable storage medium embodying computer program code, the non-transitory, computer-readable storage medium being coupled to the data bus, the computer program code interacting with a plurality of computer operations and comprising instructions executable by the processor and configured for: monitoring an information handing system chassis for presence of liquid within the information handing system chassis; determining when liquid is detected within the chassis of the information handing system chassis; and, reporting presence of liquid when liquid is detected within the information handling system chassis, the reporting being via generation of a sequence of light flashes, the sequence of light flashes being based upon a unique signal generation parameter.

In another embodiment, the invention relates to a non-transitory, computer-readable storage medium embodying computer program code, the computer program code comprising computer executable instructions configured for: monitoring an information handing system chassis for presence of liquid within the information handing system chassis; determining when liquid is detected within the chassis of the information handing system chassis; and, reporting presence of liquid when liquid is detected within the information handling system chassis, the reporting being via generation of a sequence of light flashes, the sequence of light flashes being based upon a unique signal generation parameter.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a schematic view of an example server type information handling system which incorporates an activity-light-based parameter reporting system.

FIG. 5 shows a block diagram view of a data center rack within an IT environment.

FIG. 6 shows a flowchart of a reporting component parameter operation.

FIG. 7 shows a table representing a plurality of signal generation parameters.

FIG. 8 shows a graphical representation of examples signals used to generate a plurality of signal generation parameters.

### DETAILED DESCRIPTION

Various aspects of the present disclosure include an appreciation that it is known to provide information handling systems with optical leak sensing. Various aspects of the present disclosure include an appreciation that optical leak sensing often generates a plurality of flashing lights within a chassis such as a server type information handling system chassis. Various aspects of the present disclosure include an appreciation that it would be desirable to prevent accidental or malicious attempts to sense or trigger the flashing lights.

Various aspects of the present disclosure include an appreciation that certain flashing lights are generated using a sequence generated using a sine wave. Various aspects of the present disclosure include an appreciation that the sequence generated using the sine wave is measured to determine when liquid is detected.

A system and method are disclosed for controlling activation of a sequence of activity light flashes for use with an optical leak sensing system. In certain embodiments, the sequence of activity light flashes is generated using a wideband pseudo random signal convolution operation. In certain embodiments, the sequence of activity light flashes is activated by encoding and decoding a sine wave with a pseudo random number (PN). In certain embodiments, bits of the pseudo random number are generated for each sample using a linear feedback shift register (LFSR). In certain embodiments, the sequence of activity light flashes being activated by encoding and decoding the sine wave use exclusive OR (XOR) polarity inversion with a chipping code.

In certain embodiments, the LFSR is not reset after first power-up. In certain embodiments, the length of the PN code is 2047 bits. In certain embodiments, the length of the trapezoid is 2048 samples. In certain embodiments, the PN code slides by 1 bit on each period, so the overall waveform repetition is 4094 seconds, virtually impossible to tamper with or accidentally match.

In certain embodiments, the encoding spreads the narrow spectrum of the sine wave into a broadband signal. In certain embodiments, the decoding de-spreads the broadband signal back to a narrow signal. In certain embodiments, the decoding also spreads any uncorrelated noise (e.g., noise from power grid, ambient noise, etc.). In certain embodiments, the decoding is performed via a narrow band amplitude detection operation. In certain embodiments, the narrow band amplitude detection operation only observes a fundamental frequency of the encoded signal. In certain embodiments, by only observing the fundamental frequency of the encoded signal, the narrow band amplitude detection operation rejects all other noise.

Such a system and method provide a novel variation of spread spectrum that is optimized for leak detection in a server type information handling system. Such a system and method advantageously uses a wide spectrum and rejects narrow band noise. In certain embodiments, the encoding generates a plurality of optimal pseudo random number keys. In certain embodiments, each of the plurality of optimal pseudo random number keys are assigned to respective leak sending devices. By being so assigned, the respective leak sensing devices generate unique flashing sequences that will not interfere with other leak sensing devices. In certain embodiments, the plurality of optimal pseudo random number keys includes 23 optimal 11-bit pseudo random number keys. In certain embodiments, the pseudo random number keys function similarly to a coder/decoder (CODEC) device which codes and decodes transformations of data.

In certain embodiments, the unique flashing sequences provide greater eye safety when compared with known flashing sequences. In certain embodiments, the unique flashing sequences provide similar average transmitted power when compared with known flashing sequences but peak power is far less when compared with known flashing sequences. In certain embodiments, the unique flashing sequences reduce signal spikes because the unique flashing sequences spectrally appear as noise. In certain embodiments, the unique flashing sequences provide anti-tamper function as the sequences make it difficult to maliciously or accidentally tampering with sensors.

In certain embodiments, the unique flashing sequences are difficult to reverse engineer or to generate a replay attack. In certain embodiments, because the LFSR is not a power of 2 (e.g., a length of 2047 values), so the LFSR is mismatched to a sine wave (e.g., a length of 2048 values). In certain embodiments, the LFSR pattern has a long repeat pattern (e.g., the LFSR pattern repeats every 4096 seconds (68.2 minutes)). Being so mismatched and having such a long repeat pattern resists analysis of the flashing sequence on an observation device such as an oscilloscope. In certain embodiments, the unique flashing sequences de-emphasize a need for precise clocks so that a plurality of devices can operate concurrently and asynchronously, and not disturb one another. In certain embodiments, decoding of the flashing sequences reject power noise such as 50 Hz and 60 Hz power noise. Such a system and method advantageously increases the overall performance of an optical leak detection system.

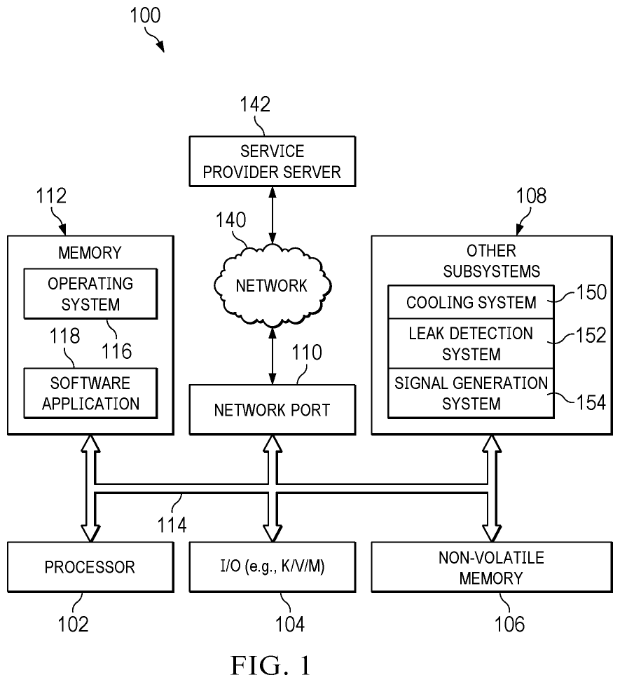

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a cooling system 150, a leak detection system 152, a signal generation system 154, or a combination thereof. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the signal generation system 154 controls activation of a sequence of activity light flashes for use with the leak detection system 152. In certain embodiments, the sequence of activity light flashes is generated using a wideband pseudo random signal convolution operation. In certain embodiments, the sequence of activity light flashes is activated by encoding and decoding a sine wave with a pseudo random number (PN). In certain embodiments, bits of the pseudo random number are generated for each sample using a linear feedback shift register (LFSR). In certain embodiments, the sequence of activity light flashes being activated by encoding and decoding the sine wave use exclusive OR (XOR) polarity inversion with a chipping code.

In certain embodiments, the LFSR is not reset after power-up of the information handling system 100. In certain embodiments, the length of the PN code is 2047 bits. In certain embodiments, the length of the trapezoid used to generate the sequence of activity light flashes is 2048 samples. In certain embodiments, the PN code slides by 1 bit on each period, so the overall waveform repetition is 4094 seconds, virtually impossible to tamper with or accidentally match.

In certain embodiments, the encoding spreads the narrow spectrum of the sine wave into a broadband signal. In certain embodiments, the decoding de-spreads the broadband signal back to a narrow signal. In certain embodiments, the decoding also spreads any uncorrelated noise (e.g., noise from power grid, ambient noise, etc.). In certain embodiments, the decoding is performed via a narrow band amplitude detection operation. In certain embodiments, the narrow band amplitude detection operation only observes a fundamental frequency of the encoded signal. In certain embodiments, by only observing the fundamental frequency of the encoded signal, the narrow band amplitude detection operation rejects all other noise.

Such a signal generation system 154 provides a novel variation of spread spectrum that is optimized for leak detection in a server type information handling system. Such a signal generation system 154 advantageously uses a wide spectrum and rejects narrow band noise. In certain embodiments, the encoding generates a plurality of optimal pseudo random number keys. In certain embodiments, each of the plurality of optimal pseudo random number keys is assigned to respective leak sending devices. By being so assigned, the respective leak sensing devices generate unique flashing sequences that will not interfere with other leak sensing devices. In certain embodiments, the plurality of optimal pseudo random number keys includes 23 optimal 11-bit pseudo random number keys. In certain embodiments, the pseudo random number keys function similarly to a coder/decoder (CODEC) device which codes and decodes transformations of data.

In certain embodiments, the unique flashing sequences provide greater eye safety when compared with known flashing sequences. In certain embodiments, the unique flashing sequences provide similar average transmitted power when compared with known flashing sequences but peak power is far less when compared with known flashing sequences. In certain embodiments, the unique flashing sequences reduce signal spikes because the unique flashing sequences spectrally appear as noise. In certain embodiments, the unique flashing sequences provide anti-tamper function as the sequences make it difficult to maliciously or accidentally tampering with sensors.

In certain embodiments, the unique flashing sequences are difficult to reverse engineer or to generate a replay attack. In certain embodiments, because the LFSR is not a power of 2 (e.g., a length of 2047 values), so the LFSR is mismatched to a sine wave (e.g., a length of 2048 values). In certain embodiments, the LFSR pattern has a long repeat pattern (e.g., the LFSR pattern repeats every 4096 seconds (68.2 minutes)). Being so mismatched and having such a long repeat pattern resists analysis of the flashing sequence on an observation device such as an oscilloscope. In certain embodiments, the unique flashing sequences de-emphasize a need for precise clocks so that a plurality of devices can operate concurrently and asynchronously, and not disturb one another. In certain embodiments, decoding of the flashing sequences reject power noise such as 50 Hz and 60 Hz power noise. Such a system and method advantageously increases the overall performance of an optical leak detection system.

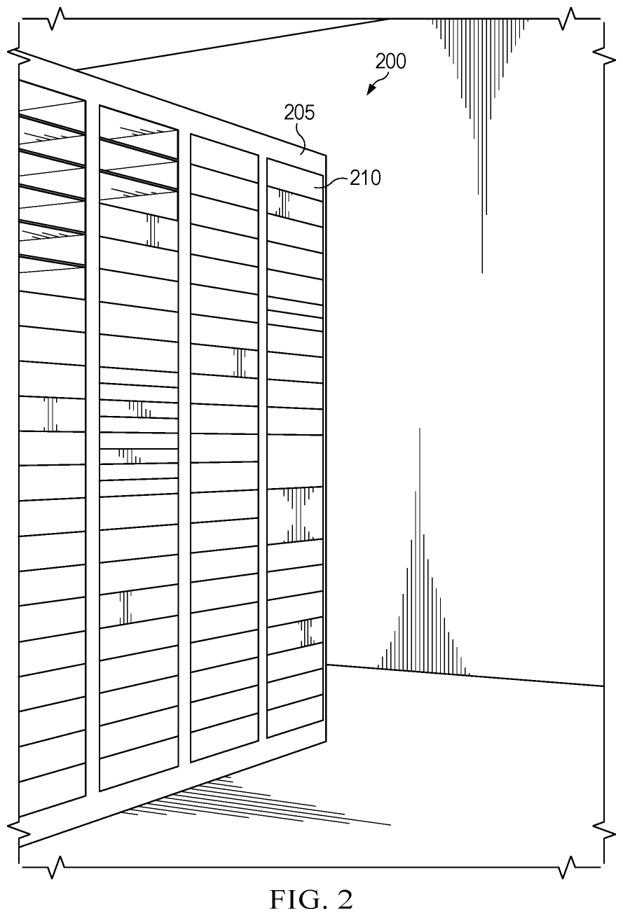

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high.

In certain embodiments, some or all of the information handling systems 210 are configured as fluid cooled information handling systems. In certain embodiments, the fluid cooled information handling systems correspond to systems having high powered heat producing components. In certain embodiments, other information handling systems 210 are configured as air cooled information handling systems. In certain embodiments, the air cooled information handling systems correspond to systems that do not require fluid cooling to function properly.

In certain embodiments, the rack includes a coolant distribution unit. In certain embodiments, the fluid cooled information handling systems are thermally coupled with the cooling distribution unit. In certain embodiments, the coolant distribution unit provides a closed loop via which the coolant is provided to and removed from the fluid cooled information handling systems. In certain embodiments, the coolant distribution unit can simultaneously facilitate cooling of multiple information handling systems.

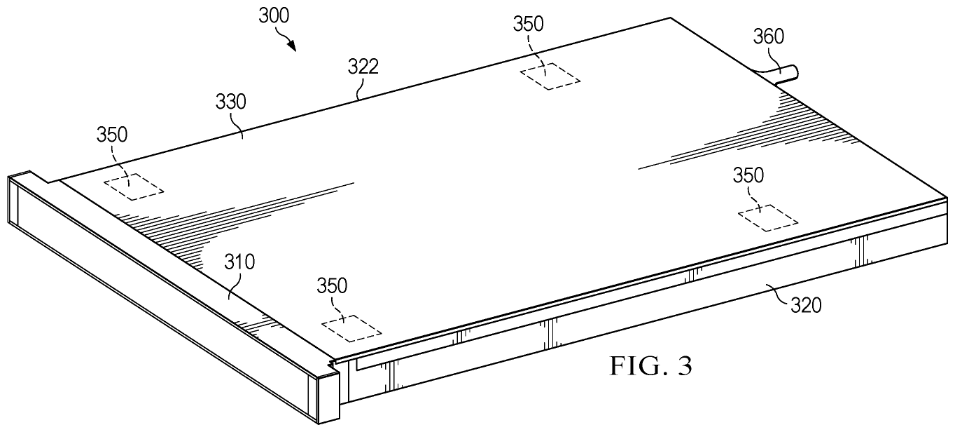

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes one or more leak detection systems 350. In certain embodiments, the leak detection systems 350 are positioned in a plurality of locations within the information handling system 300. In certain embodiments, the information handling system 300 includes a liquid cooling intake/outtake 360.

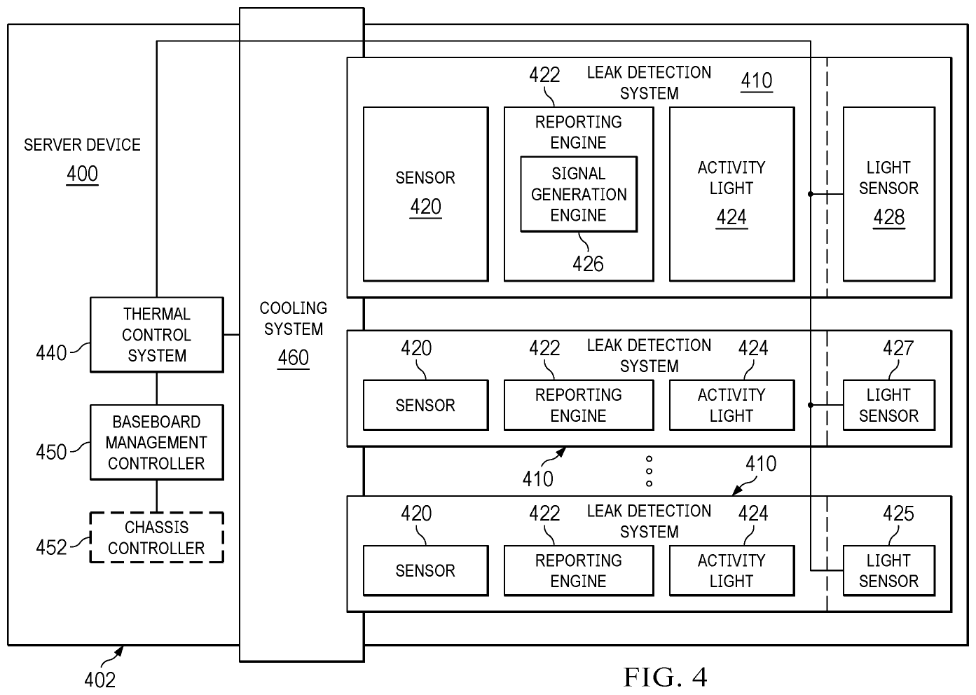

FIG. 4 shows a schematic view of an example server type information handling system 400 which incorporates an activity-light-based parameter reporting system. The server type information handling system 400 corresponds to the information handling system 100. It will be appreciated that, while the activity-light-based parameter reporting system is shown within a storage device of a server type information handling system such an activity-light-based parameter reporting system may be applied to components in storage systems (e.g., Redundant Array of Independent Disk (RAID) systems), networking systems (e.g., switches, routers, etc.), desktop computing devices, laptop/notebook computing devices, or a combination thereof.

In various embodiments, the server type information handling system 400 includes a chassis 402 that houses the components of the server type information handling system 400. For example in certain embodiments, the chassis 402 houses a plurality of leak detection systems 410. However, it will be appreciated that components using the activity-light-based parameter reporting system may include any components that are configured to report their activity via an associated activity light, and that are associated with parameters that may be reported via sideband communications using that activity light as well.

In certain embodiments, each leak detection system 410 includes a parameter sensor 420, a reporting engine 422, an activity light 424, or a combination thereof. In certain embodiments, one or more reporting engines 422 include a respective signal generation engine 426. In certain embodiments, the chassis 402 further includes one or more light sensors 428. In certain embodiments, each leak detection system 410 includes a respective light sensor. In certain embodiments, the one or more light sensors 428 are configured to detect when an activity light 424 is generating light. In certain embodiments, the one or more light sensors 428 are configured to detect a sequence of light generated by an activity light. In certain embodiments, the sequence of light is generated according to a signal generated by the signal generation engine 426.

In certain embodiments, the parameter sensor 420 includes a liquid sensor that is configured to detect presence of liquid within the chassis 402 generated by one or more components of the server type information handling system. In certain embodiments, the liquid that detected is proximate to a particular leak detection system. However, it will be appreciated that the parameter sensor 420 may be configured to sense any parameter of interest associated with the server type information handling system 400. The leak detection system 410 may also include a processing system (e.g., not illustrated, but which may include processor such as processor 102, a portion of firmware, a portion of a controller, and/or other processing components) and a memory system (e.g., not illustrated, but which may include the memory 112, a portion of firmware, a portion of a controller, and/or other memory components) that is coupled to the processing system and that includes instructions that, when executed by the processing system, cause the processing system to provide some or all of the parameter reporting engine 422 which is configured to perform the functionality of the parameter reporting engines and storage devices discussed below. The parameter reporting engine 422 is coupled to the parameter sensor 420, as well as to the activity light 426. In certain embodiments, the activity light 426 which may be provided by a light component. In certain embodiments, the activity light 426 includes a Light Emitting Device (LED). In certain embodiments, each light sensor 428 includes a respective photodiode.

In certain embodiments, the chassis 402 also houses a thermal control system 440. In certain embodiments, the thermal control system 440 interacts with the one or more liquid detection systems 404. In certain embodiments, the chassis 402 houses a baseboard management controller (BMC) 450, a chassis controller 452, or a combination thereof. In certain embodiments, the baseboard management controller 450 is coupled to the thermal control system 440. In certain embodiments, the baseboard management controller 450 includes an integrated DELL® Remote Access Controller (iDRAC) available from DELL® Inc. of Round Rock, Texas, United States.

In certain embodiments, a cooling system 460 is housed in the chassis 402. In certain embodiments, the thermal control system 440, the BMC 450, the chassis controller 452, or a combination thereof, are coupled to the cooling system 460. In certain embodiments, the chassis controller 452 is housed in the chassis 402 or in a rack in which the chassis 402 is mounted, or a combination thereof. In various embodiments, the cooling system 460 includes fans, fan controllers, heat sinks, heat pipes, liquid cooling components, or a combination thereof.

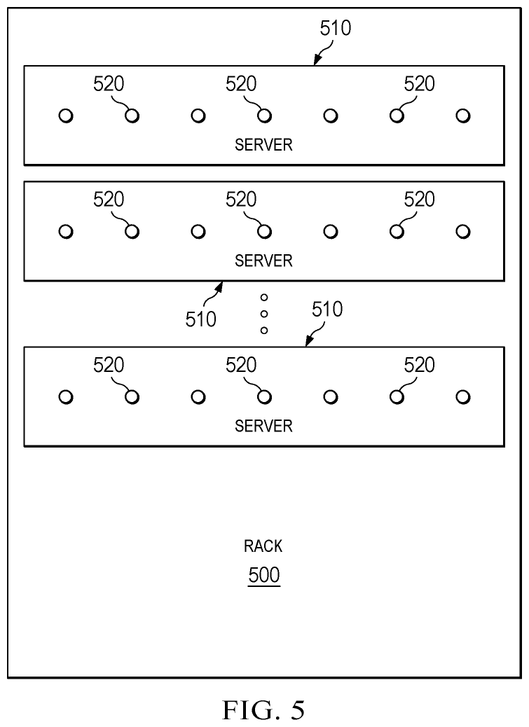

FIG. 5 shows a block diagram view of a data center rack 500 within an IT environment. In certain embodiments, the data center rack 500 includes a plurality of server type information handling systems 510. In certain embodiments, each server type information handling system 510 corresponds to an information handling system 100. In various embodiments, each server type information handling system 510 includes a respective plurality of component activity lights 520. In certain embodiments, the plurality of component activity lights 520 are visible on a front surface of a server type information handing system 510, when a top panel of a server type information handling system 510 is open, or a combination thereof. In certain embodiments, each server type information handling system 510 includes a light sensor (not shown in FIG. 5) which senses when a respective component activity light 520 is activated.

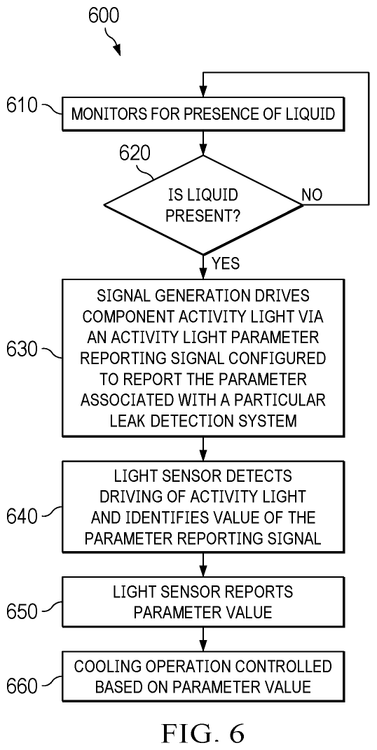

FIG. 6 shows a flowchart of a parameter detection reporting operation 600 using a component activity light. In certain embodiments, the parameter detection reporting operation 600 includes a leak detection parameter reporting operation. In certain embodiments, the parameter detection reportion operation 600 provides activity light based parameter reporting that diminishes certain visual side effect issues common to activity light based parameter reporting. In certain embodiments, the activity light based parameter reporting controls a sequence of light flashes produced by the component activity light to reduce visual side effects associated with such reporting that may be concerning to users.

More specifically, the leak detection parameter reporting operation 600 begins at step 610 with a leak detection device monitoring for presence of liquid within the information handling system. In certain embodiments, the monitoring is performed on a portion of an information handling system chassis proximate to the leak detection device. Next at step 620, the leak detection system determines whether liquid is present at the portion of an information handling system chassis proximate to a leak detection device. Next at step 630, a signal generation engine provides a unique flash sequence signal to the activity light of the leak detection system which detected the presence of liquid. In certain embodiments, the unique flash sequence corresponds to an activity light parameter reporting signal. In certain embodiments, the activity light parameter reporting signal is associated with a particular leak detection system. Next at step 640, a light sensor detects driving of the activity light and identifies the value of the activity light parameter reporting signal. Next at step 650, the light sensor reports the value of the activity light parameter reporting signal. In certain embodiments, the light sensor reports the value to a baseboard management controller, a chassis controller, a thermal control system, or a combination thereof. Next at step 670, a cooling operation is controlled based upon the value of the activity light parameter reporting signal. In certain embodiments, the cooling operation may be controlled by a baseboard management controller, a chassis controller, a thermal control system, or a combination thereof. In certain embodiments, the cooling operation controls one or more functions of a cooling system of the information handling system.

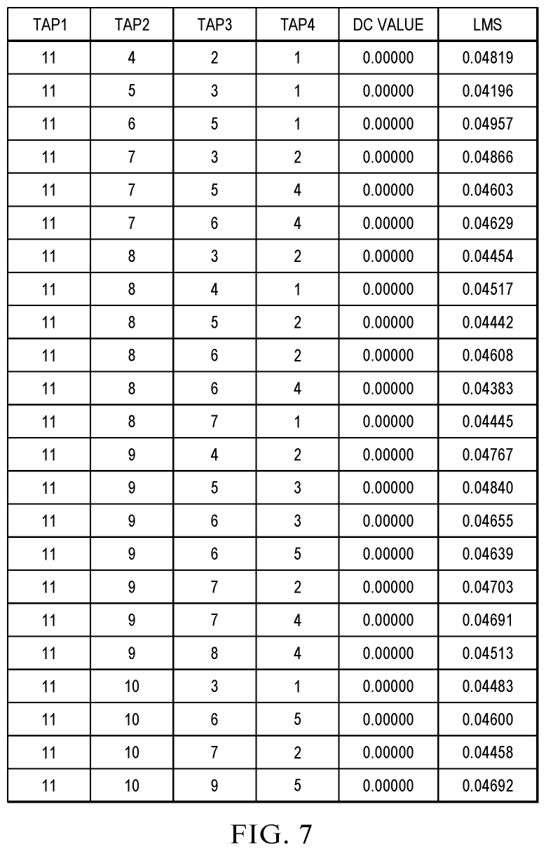

FIG. 7 shows a table representing a plurality of signal generation parameters. In certain embodiments, each of the plurality of signal generation parameters comprises a respective pseudo random number code. In certain embodiments, each of the plurality of signal generation parameters is used to generate a respective value of an activity light parameter reporting signal. In certain embodiments, the plurality of optimal pseudo random number codes are used to encode a signal such as a trapezoid signal. In certain embodiments, the plurality of pseudo random number codes are generated using a plurality of taps. In certain embodiments, the plurality of taps are provided as part of a linear feedback shift register to generate the pseudo random number codes. In certain embodiments, the plurality of pseudo random number codes is generated using four taps of linear feedback shift register. As used herein, taps broadly refers the bit positions in the LFSR that affect the next state of the LFSR. In certain embodiments, the plurality of optimal pseudo random number codes includes 23 optimal 11-bit pseudo random number codes.

In certain embodiments, an 11-bit pseudo random number key is selected from 8, 9, 10, 11, 12 and 13-bit random number code options. In certain embodiments, the 11-bit pseudo random number code provides a desirable number of usable codes. In certain embodiments, the desirable number of useable codes provides a sufficient number of unique codes to include a plurality of leak detection systems within a chassis of an information handling system such that each of the plurality of leak detection systems can generate a respective unique flashing sequence. In certain embodiments, the respective unique flashing sequences are sufficient to prevent accidental or malicious attempts to sense or trigger activity lights of respective leak detection systems. In certain embodiments, the 11-bit pseudo random number code provides 23 usable codes. In certain embodiments, the useable codes are codes which correspond to a plurality of characteristics.

In certain embodiments, these 23 optimal 11-bit pseudo random number codes are selected from a larger set of pseudo random number codes using a plurality of selectin characteristics. In certain embodiments, the plurality of selection characteristics include a low DC average characteristic, a flat spectrum characteristic, a low cross-correlation characteristic, or a combination thereof. In certain embodiments, the selection of the pseudo random number codes identifies codes having a low (e.g., zero) DC average characteristic. In certain embodiments, the low (e.g., zero) DC average characteristic identifies pseudo random number codes which avoid drift and saturation as may be present in a high gain circuit. In certain embodiments, the selection of the pseudo random number codes identifies codes having a flat spectrum characteristic. In certain embodiments, the flat spectrum characteristic identifies pseudo random number codes which optimize spreading and noise immunity. In certain embodiments, the selection of the pseudo random number codes identifies codes having a low cross-correlation characteristic. In certain embodiments, the low cross-correlation characteristic identifies a plurality of pseudo random number codes which can exist with each other with no interference. In certain embodiments, a least mean square (LMS) value associated with a pseudo random number code is used to identify codes having a low cross-correlation characteristic.

In certain embodiments, identification of pseudo random number codes corresponding to the low DC average characteristic can identify over a thousand pseudo random number codes. In certain embodiments, identification of pseudo random number codes corresponding to the flat spectrum characteristic can identify over a hundred pseudo random number codes. In certain embodiments, identification of pseudo random number codes corresponding to the cross correlation characteristic can identify 23 pseudo random number codes.

In certain embodiments, each of the plurality of optimal pseudo random number code is assigned to respective leak sensing devices. By being so assigned, the respective leak sensing devices generate unique flashing sequences that do not interfere with flashing sequences generated by other leak sensing devices.

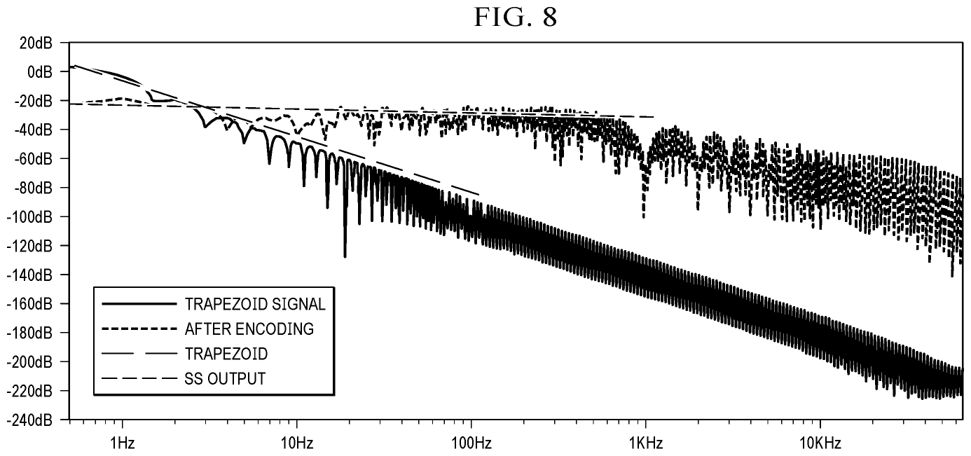

FIG. 8 shows a graphical representation of examples signals used to generate a plurality of signal generation parameters. More specifically, the example signals includes a trapezoid signal and an encoded signal, which corresponds to the trapezoid signal after being encoded. In certain embodiments, the trapezoid signal has a strong fundamental frequency with low harmonics. In certain embodiments, the trapezoid signal is used as approximation for sine wave that is easy to generate in a micro control unit (MCU). In certain embodiments, a signal generation system, such as signal generation system 154, includes a micro control unit that generates the trapezoid signal. In certain embodiments, after encoding, the encoded signal resembles broadband noise. In certain embodiments, the encoded signal comprises a spread spectrum (SS) trapezoid signal. In certain embodiments, the spread spectrum trapezoid signal is transmitted as the signal generation parameters which are used to generate the sequence of activity light flashes. In certain embodiments, the encoding, the decoding, or a combination thereof, are performed by a signal generation system.

In certain embodiments, the sequence of activity light flashes is activated by encoding and decoding a sine wave with a pseudo random number (PN). In certain embodiments, bits of the pseudo random number are generated for each sample using a linear feedback shift register (LFSR). In certain embodiments, the sequence of activity light flashes being activated by encoding and decoding the sine wave use exclusive OR (XOR) polarity inversion with a chipping code.

In certain embodiments, the LFSR is not reset after power-up of the information handling system 100. In certain embodiments, the length of the PN code is 2047 bits. In certain embodiments, the length of the trapezoid used to generate the sequence of activity light flashes is 2048 samples. In certain embodiments, the PN code slides by 1 bit on each period, so the overall waveform repetition is 4094 seconds, virtually impossible to tamper with or accidentally match.

In certain embodiments, the encoding spreads the narrow spectrum of the sine wave into a broadband signal. In certain embodiments, the decoding de-spreads the broadband signal back to a narrow signal. In certain embodiments, the decoding also spreads any uncorrelated noise (e.g., noise from power grid, ambient noise, etc.). In certain embodiments, the decoding is performed via a narrow band amplitude detection operation. In certain embodiments, the narrow band amplitude detection operation is performed by one or more light sensors associated with the leak detection system. In certain embodiments, the narrow band amplitude detection operation only observes a fundamental frequency of the encoded signal. In certain embodiments, by only observing the fundamental frequency of the encoded signal, the narrow band amplitude detection operation rejects all other noise.

Such a signal generation system provides a novel variation of spread spectrum that is optimized for leak detection in a server type information handling system. Such a signal generation system advantageously uses a wide spectrum and rejects narrow band noise. In certain embodiments, the encoding generates a plurality of optimal pseudo random number keys. In certain embodiments, each of the plurality of optimal pseudo random number keys is assigned to respective leak sending devices. By being so assigned, the respective leak sensing devices generate unique flashing sequences that will not interfere with other leak sensing devices. In certain embodiments, the plurality of optimal pseudo random number keys includes 23 optimal 11-bit pseudo random number keys. In certain embodiments, the pseudo random number keys function similarly to a coder/decoder (CODEC) device which codes and decodes transformations of data.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A method for reporting presence of liquid within an information handling system, comprising:
monitoring an information handing system chassis for presence of liquid within the information handing system chassis;
determining when liquid is detected within the chassis of the information handing system chassis; and,
reporting presence of liquid when liquid is detected within the information handling system chassis, the reporting being via generation of a sequence of light flashes, the sequence of light flashes being based upon a unique signal generation parameter.

2. The method of claim 1, wherein:
the unique signal generation parameter is based upon a pseudo random number code selected from a plurality of pseudo random number codes.

3. The method of claim 2, wherein:
the plurality of pseudo random number codes are selected based upon a plurality of selection characteristics.

4. The method of claim 3, wherein:
the plurality of selection characteristics comprise one or more of a low DC average characteristic, a flat spectrum characteristic, and a low cross-correlation characteristic.

5. The method of claim 2, wherein:
the plurality of pseudo random number codes are selected from a larger set of pseudo random number codes; and
the larger set of pseudo random number codes are encoded by spreading a sine wave into a broadband signal.

6. The method of claim 1, wherein:
the unique signal generation parameter is assigned to a particular leak sensing device; and,
the particular leak sensing device generates unique flashing sequence that does not interfere with flashing sequences generated by other leak sensing devices.

7. A system comprising:
a chassis;
a processor contained within the chassis;
a data bus coupled to the processor;
a liquid detection system contained within the chassis; and
a non-transitory, computer-readable storage medium embodying computer program code, the non-transitory, computer-readable storage medium being coupled to the data bus, the computer program code interacting with a plurality of computer operations and comprising instructions executable by the processor and configured for:
monitoring the chassis for presence of liquid within the chassis;
determining when liquid is detected within the chassis of the information handing system chassis;
reporting presence of liquid when liquid is detected within the information handling system chassis, the reporting being via generation of a sequence of light flashes, the sequence of light flashes being based upon a unique signal generation parameter.

8. The system of claim 7, wherein:
the unique signal generation parameter is based upon a pseudo random number code selected from a plurality of pseudo random number codes.

9. The system of claim 8, wherein:
the plurality of pseudo random number codes are selected based upon a plurality of selection characteristics.

10. The system of claim 9, wherein:
the plurality of selection characteristics comprise one or more of a low DC average characteristic, a flat spectrum characteristic, and a low cross-correlation characteristic.

11. The system of claim 8, wherein:
the plurality of pseudo random number codes are selected from a larger set of pseudo random number codes; and
the larger set of pseudo random number codes are encoded by spreading a sine wave into a broadband signal.

12. The system of claim 7, wherein:
the unique signal generation parameter is assigned to a particular leak sensing device; and,
the particular leak sensing device generates unique flashing sequence that does not interfere with flashing sequences generated by other leak sensing devices.

13. A non-transitory, computer-readable storage medium embodying computer program code, the computer program code comprising computer executable instructions configured for:
monitoring an information handing system chassis for presence of liquid within the information handing system chassis;
determining when liquid is detected within the chassis of the information handing system chassis;
reporting presence of liquid when liquid is detected within the information handling system chassis, the reporting being via generation of a sequence of light flashes, the sequence of light flashes being based upon a unique signal generation parameter.

14. The non-transitory, computer-readable storage medium of claim 13, wherein:
the unique signal generation parameter is based upon a pseudo random number code selected from a plurality of pseudo random number codes.

15. The non-transitory, computer-readable storage medium of claim 14, wherein:
the plurality of pseudo random number codes are selected based upon a plurality of selection characteristics.

16. The non-transitory, computer-readable storage medium of claim 15, wherein:
the plurality of selection characteristics comprise one or more of a low DC average characteristic, a flat spectrum characteristic, and a low cross-correlation characteristic.

17. The non-transitory, computer-readable storage medium of claim 13, wherein:
the plurality of pseudo random number codes are selected from a larger set of pseudo random number codes; and
the larger set of pseudo random number codes are encoded by spreading a sine wave into a broadband signal.

18. The non-transitory, computer-readable storage medium of claim 13, wherein:
the unique signal generation parameter is assigned to a particular leak sensing device; and,
the particular leak sensing device generates unique flashing sequence that does not interfere with flashing sequences generated by other leak sensing devices.

19. The non-transitory, computer-readable storage medium of claim 13, wherein:
the computer executable instructions are deployable to a client system from a server system at a remote location.

20. The non-transitory, computer-readable storage medium of claim 13, wherein:
the computer executable instructions are provided by a service provider to a user on an on-demand basis.
